(19) United States
(12) Patent Application Publication
(10) Pub. No.: US 2026/0198280 A1
(43) Pub. Date: Jul. 9, 2026

(54) SEMICONDUCTOR DEVICE AND METHOD FOR FORMING THE SAME

(71) Applicant: TAIWAN SEMICONDUCTOR MANUFACTURING COMPANY LTD., HSINCHU (TW)

(72) Inventors: CHUN-HAO LIN, TAINAN CITY (TW); YU-JEN WANG, KAOHSIUNG CITY (TW); CHUN-HAO CHOU, TAINAN CITY (TW)

(21) Appl. No.: 19/012,950

(22) Filed: Jan. 8, 2025

(51) Int. Cl. H01L 23/48; H01L 21/768; H01L 23/00; H01L 25/07

(52) U.S. Cl. CPC H10W 20/20; H10W 20/023; H10W 20/076; H10W 90/00; H10W 80/327; H10W 90/297; H10W 90/792

(57) ABSTRACT

A semiconductor device is provided. The semiconductor device includes a first semiconductor chip, a second semiconductor chip bonded to the first semiconductor chip, a conductive plug, and a dielectric structure surrounding a portion of the sidewall of the conductive plug. The conductive plug extends from the first semiconductor chip to the second semiconductor chip for electrically connecting the first metallization structure and the second metallization structure. The dielectric structure includes a middle dielectric layer between an outer dielectric layer and an inner dielectric layer. The outer dielectric layer is formed between the first substrate and the middle dielectric layer. The dielectric constant of the outer dielectric layer is greater than the dielectric constant of the middle dielectric layer.

### BACKGROUND

The semiconductor industry has experienced rapid growth due to continuous improvements in the integration density of a variety of electronic components (e.g., transistors, diodes, resistors, capacitors, etc.). As semiconductor technologies further advance, stacked semiconductor devices have emerged as an effective way to further reduce the physical size of a semiconductor device. In a stacked semiconductor device using wafer-on-wafer stacking technology, image sensors such as complementary metal-oxide-semiconductor (CMOS) image sensor, active circuits such as logic, memory, processor circuits and the like are fabricated on different semiconductor wafers or chips. Two or more semiconductor wafers or chips may be installed on top of one another and are bonded together through suitable bonding techniques. A through-via (such as through-oxide via (TOV) or the like) that crosses the wafer bonding interface electrically connects the electrical and/or optical components of two stacked wafers or chips of the semiconductor device.

However, conventional semiconductor devices having stacked wafers or chips suffer from current leakage due to weak passivation and electrical isolation around the through-via. In addition, components (such as photodetectors) positioned in proximity to the through-via must be maintained at a certain distance from the through-via to prevent any adverse impact on their electrical or optical performance.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a flowchart illustrating a method of forming a semiconductor device, in accordance with some embodiments of the present disclosure.

FIG. 2A-FIG. 2I are fragmentary cross-sectional views of a semiconductor device at different stages of fabrication, in accordance with some embodiments of a method in FIG. 1.

FIG. 3A-FIG. 3G illustrate enlarged cross-sectional views of a region shown in FIG. 2I in accordance with various embodiments.

FIG. 4 illustrates a fragmentary cross-sectional view of a semiconductor device, in accordance with some embodiments of the present disclosure.

FIG. 5 illustrates a fragmentary cross-sectional view of a semiconductor device, in accordance with some embodiments of the present disclosure.

FIG. 6 illustrates a fragmentary cross-sectional view of a semiconductor device, in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the like thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

Embodiments of the present disclosure provide a semiconductor device and a method for forming the semiconductor device. The semiconductor device includes at least two semiconductor chips, a conductive plug electrically connecting the semiconductor chips, and a dielectric structure surrounding a portion of the conductive plug. The conductive plug and the dielectric structure of the embodiments construct a high-quality electrical interconnection structure with a high-k dielectric liner, thereby greatly enhancing the passivation and electrical isolation around the conductive plug. Therefore, the electrical and/or optical performance of the semiconductor device, in accordance with embodiments of the present disclosure, can be improved. In addition, a keep-out zone (KOZ) between an array region and the electrical interconnection structure of the embodiments can be reduced, thereby increasing flexibility in circuit design.

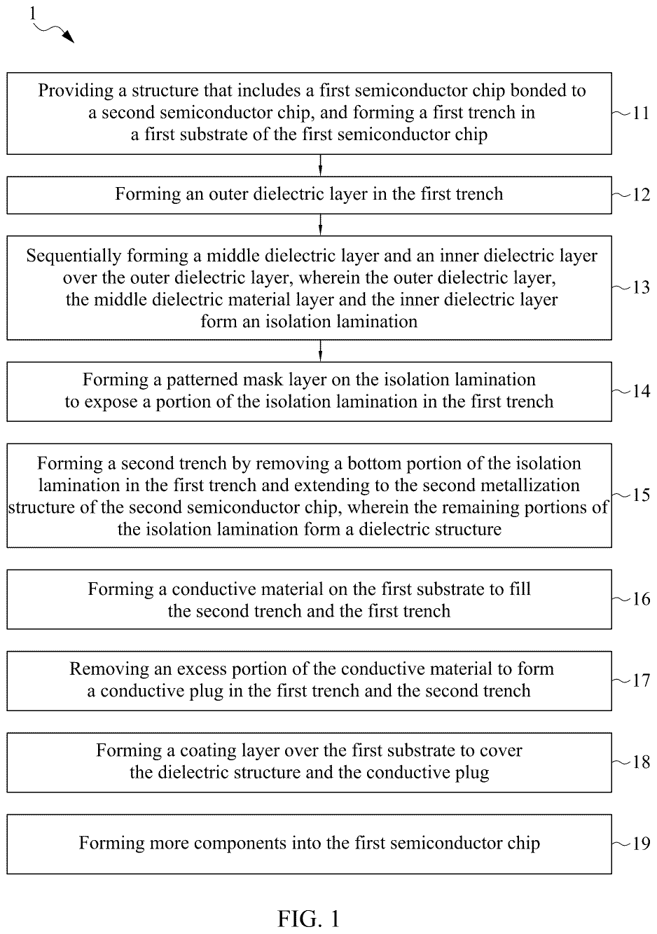

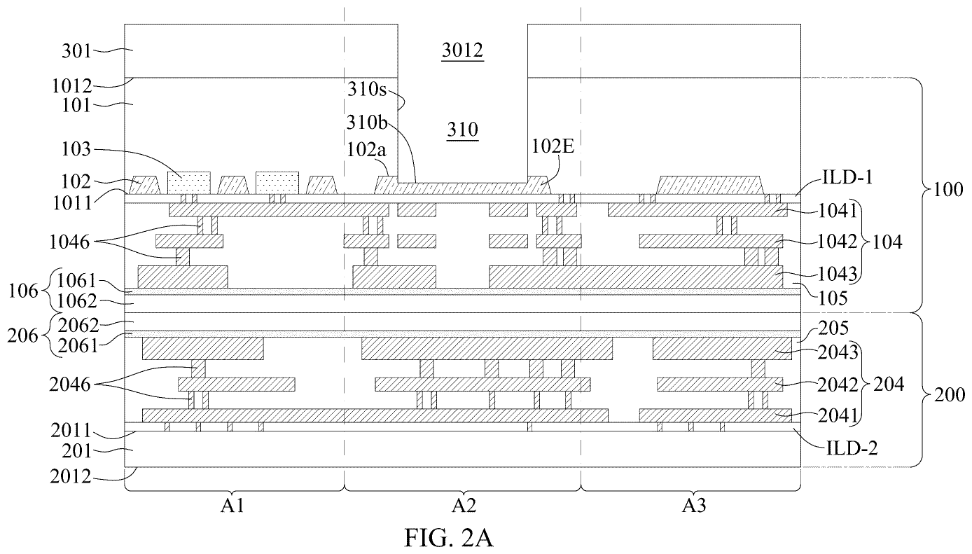

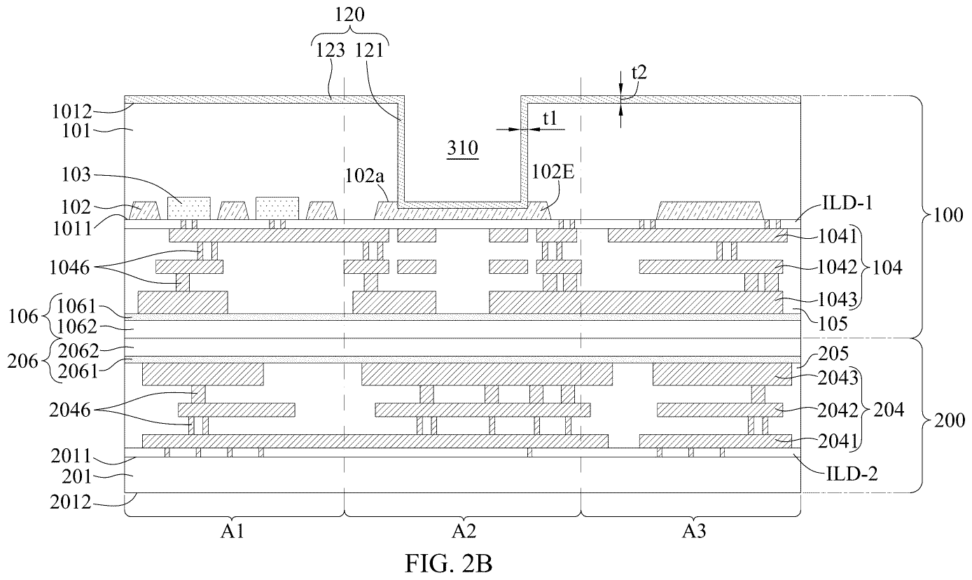

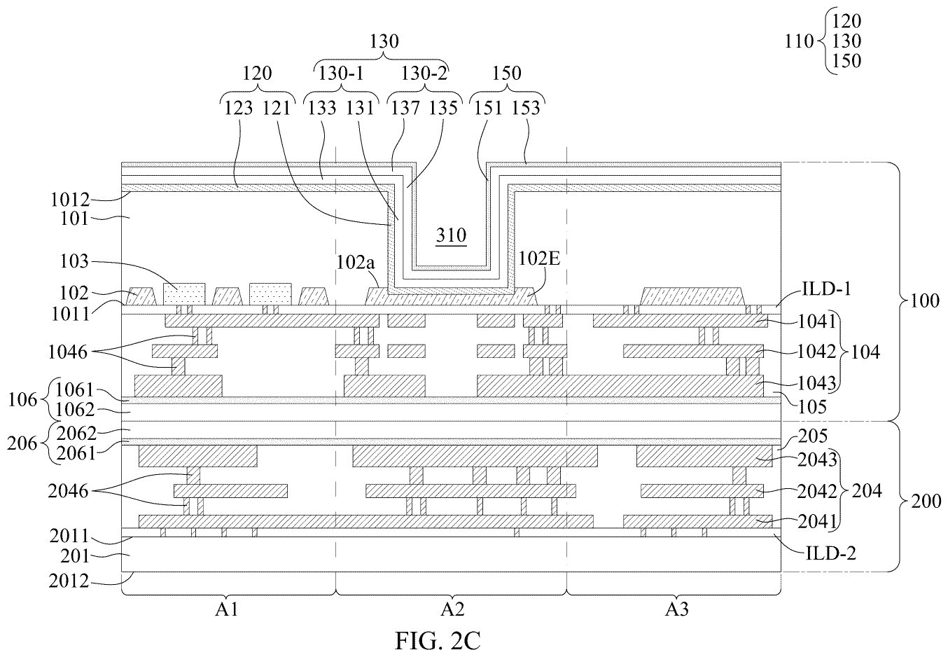

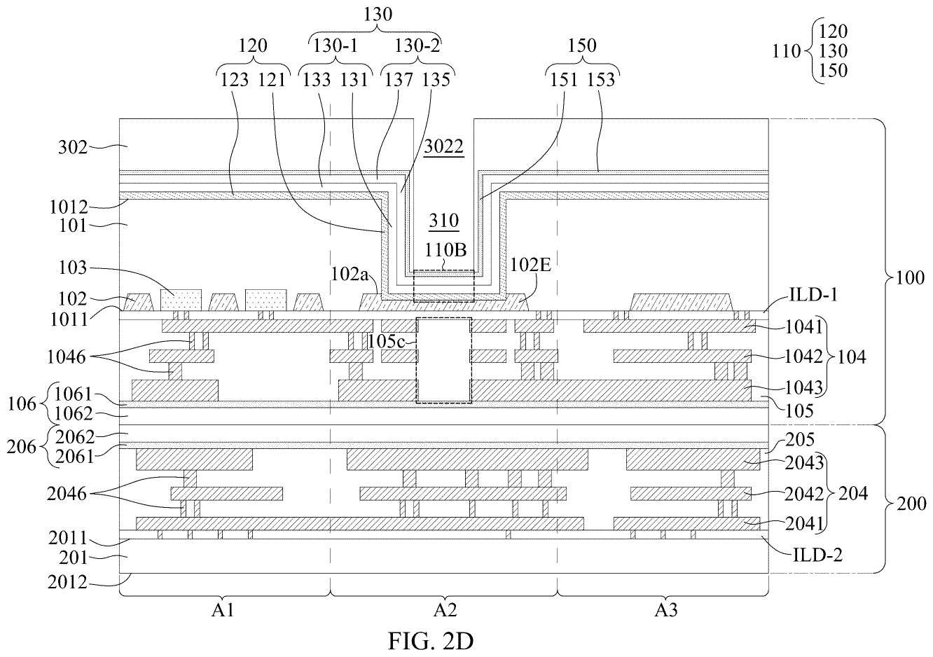

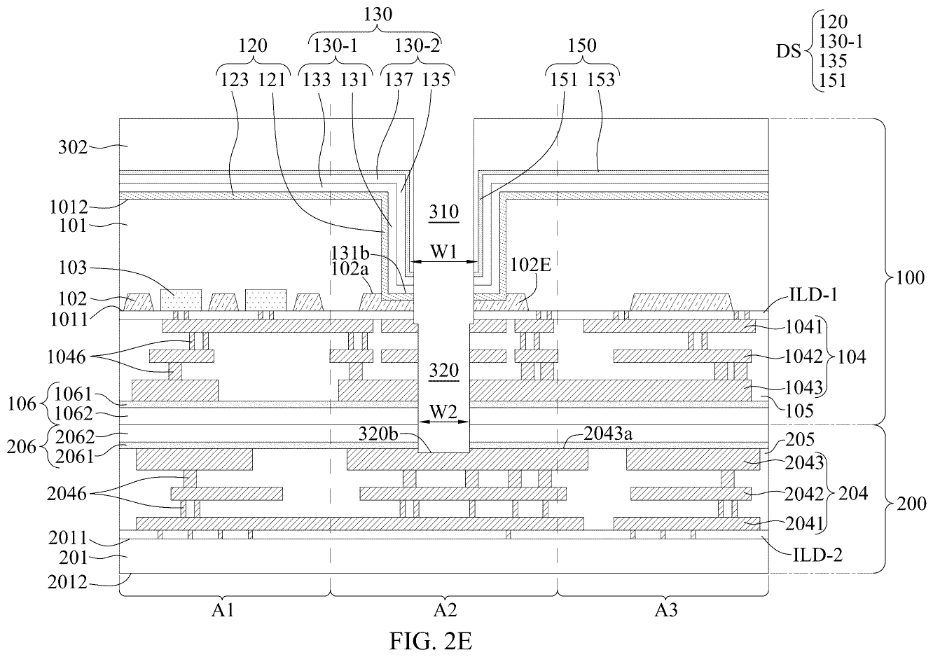

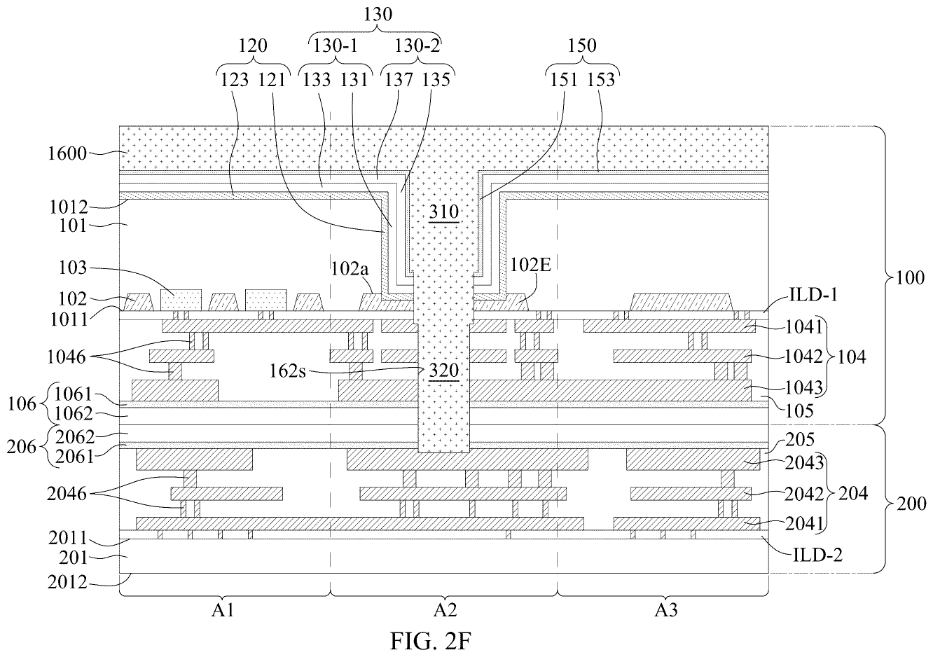

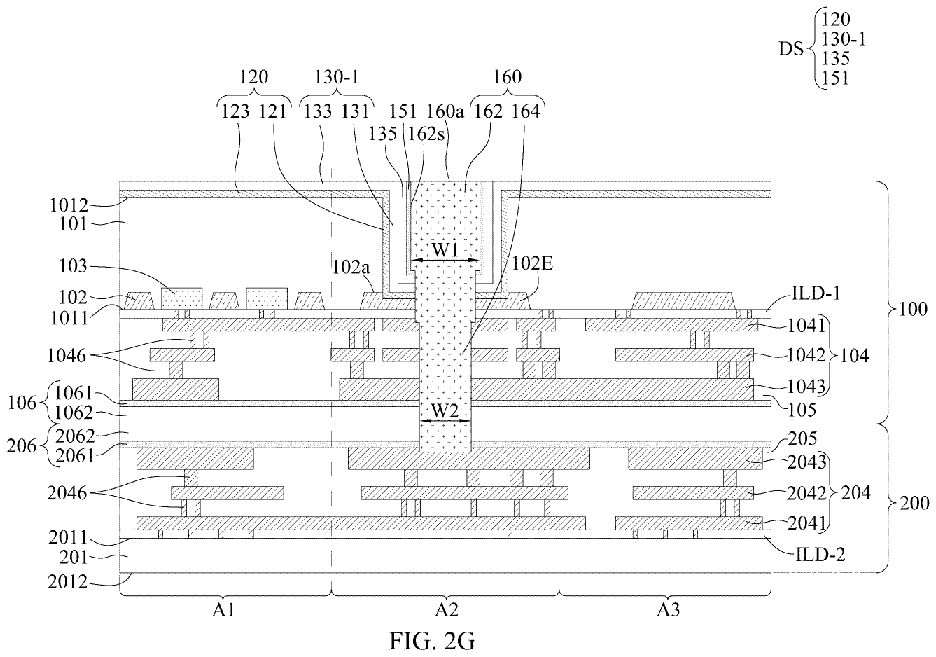

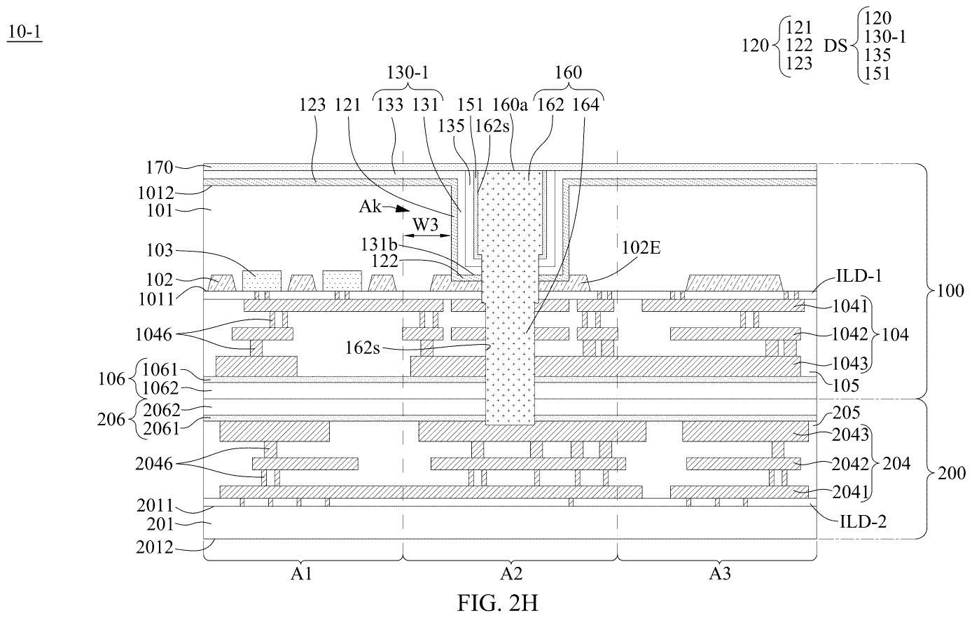

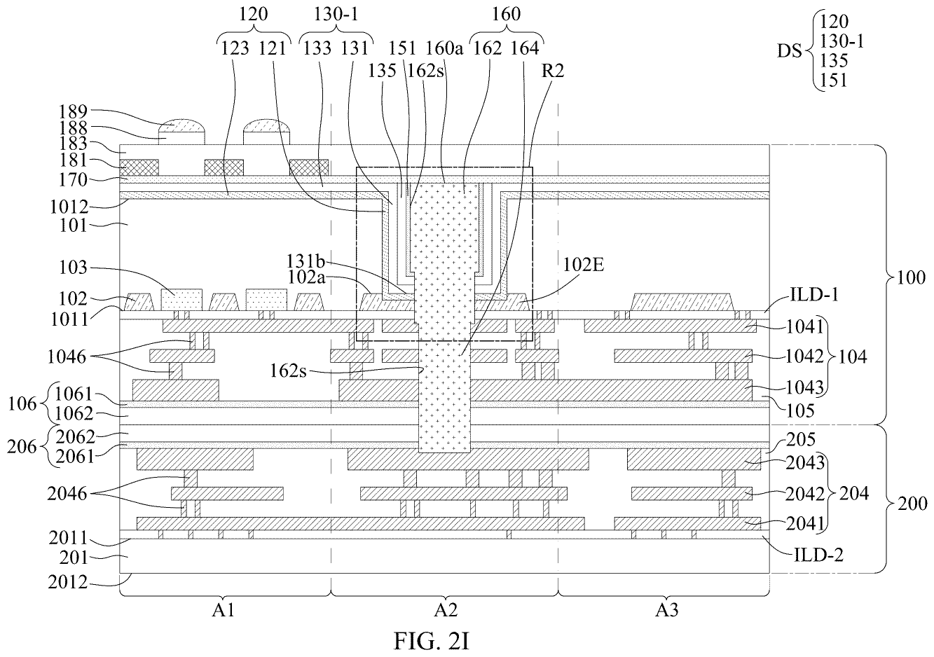

The various aspects of the present disclosure will now be described in more detail with reference to the figures. FIG. 1 is a flowchart illustrating a method of forming a semiconductor device 10-1, in accordance with some embodiments of the present disclosure. FIG. 2A-FIG. 2I are fragmentary cross-sectional views of a semiconductor device 10-1 at different stages of fabrication in accordance with some embodiments of method 1 in FIG. 1. The semiconductor device 10-1 may be an image sensor device, such as a three-dimensional (3D) stacked complementary metal-oxide-semiconductor (CMOS) image sensor (CIS) device, or another suitable device.

Referring to FIG. 1 and FIG. 2A, method 1 includes a block 11 where a structure that includes a first semiconductor chip 100 bonded to a second semiconductor chip 200 is provided, and a first trench 310 is formed in a first substrate 101 of the first semiconductor chip 100. In some embodiments, the first semiconductor chip 100 is configured as an image sensing chip, such as a back side illuminated (BSI) image sensor chip. In some embodiments, the first semiconductor chip 100 may include an array region A1, a through-oxide via (TOV) region A2, and a pad region A3.

In some embodiments, the first semiconductor chip 100 includes a first substrate 101. The first substrate 101 may be formed of group III, group IV, group V elements or combinations thereof. In some embodiments, the first substrate 101 includes silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb), indium phosphide (InP), or combinations thereof. The first substrate 101 may be doped or undoped. In one embodiment, the first substrate 101 is a silicon substrate doped with a p-type dopant such as boron (a p-type substrate). In another embodiment, the first substrate 101 is a silicon substrate doped with an n-type dopant such as phosphorus or arsenic (an n-type substrate). The first substrate 101 may be a bulk semiconductor substrate, such as a bulk silicon substrate that is a wafer, a silicon-on-insulator (SOI) substrate, a multi-layered or gradient substrate, hybrid orientation substrates, any combination thereof, and/or the like. The SOI substrate may include a layer of a semiconductor material (e.g., silicon, germanium, and/or the like) formed over an insulator layer (e.g., buried oxide and/or the like), which is formed on a silicon substrate.

In the first semiconductor chip 100, various features are included and disposed in and over the first substrate 101. For example, several isolation structures 102 are formed on the first surface 1011 and protrude toward the second surface 1012 of the first substrate 101. The isolation structures 102 are buried in the first substrate 101, and may be shallow trench isolation (STI), deep trench isolation (DTI), or a combination thereof. In some embodiments, the isolation structures 102 in the array region A1 define several pixel areas (or device areas). The first substrate 101 may include some devices such as photodiodes and transistors in the pixel areas. In some embodiments, where the first semiconductor chip 100 is a semiconductor image sensor chip (or a sensor wafer), the pixel areas may include pixel sensors operable to detect radiation, such as an incident light, which is projected toward the first substrate 101 from the backside (e.g., the second surface 1012) of the first substrate 101.

In some embodiments, several devices such as the photodetectors 103 may be formed in the first substrate 101 and separated from each other by the isolation structures 102. The photodetectors 103 are, for example, photodiodes or any suitable photodetecting devices disposed in the corresponding pixel areas. The photodetectors 103 in the pixel regions are configured to convert incident radiation or incident light into an electric signal. The isolation structures 102 and the subsequently formed metal grids (FIG. 2I) block light from passing between neighboring pixels and prevent interpixel cross talk. The isolation structures 102 may include a dielectric material, such as silicon oxide, silicon nitride, silicon oxynitride, a low-k dielectric, or any suitable dielectric material.

In some embodiments, the first semiconductor chip 100 further includes a first metallization structure 104, a first inter-metal dielectric (IMD) layer 105, and a first inter-layer dielectric layer ILD-1 between the first IMD layer 105 and the first surface 1011 of the first substrate 101. In some embodiments, the first metallization structure 104 includes a first metallization layer 1041, a top metallization layer 1043, and interconnect layers 1042 between the first metallization layer 1041 and the top metallization layer 1043. In some embodiments, the first metallization layer 1041 is disposed adjacent to the isolation structures 102, and the top metallization layer 1043 is disposed adjacent to an interface defined between the first semiconductor chip 100 and the second semiconductor chip 200. In addition, there are conductive contacts between the first metallization layer 1041 and the first substrate 101 for electrically connecting the first metallization structure 104 and the devices (such as the photodetectors 103) in the first substrate 101. In some embodiments, the first metallization structure 104 further includes conductive vias 1046 between metal layers of the interconnect layer 1042, the first metallization layer 1041 and the top metallization layer 1043 for electrical connection. In some embodiments, the first metallization structure 104 forms a first back-end-of-line (BEOL) structure for the first semiconductor chip 100.

The first inter-layer dielectric layer ILD-1 may be formed of silicon oxide or another suitable dielectric material. The first metallization structure 104 may include gold, silver, copper, nickel, tungsten, aluminum, palladium and/or alloys thereof. The first IMD layer 105 may be formed of a low-k dielectric material, such as phosphosilicate glass (PSG), borophosphosilicate glass (BPSG), FSG, SiOxCy, Spin-On-Glass, Spin-On-Polymers, silicon carbon material, compounds thereof, composites thereof, combinations thereof, or the like. The first IMD layer 105 may be formed by any suitable method, such as spin-on coating, chemical vapor deposition (CVD), or plasma-enhanced CVD (PECVD).

In some embodiments, the second semiconductor chip 200 is configured as a semiconductor application specific integrated circuit (ASIC) chip. In some embodiments, the second semiconductor chip 200 includes several logic circuits such as a data processing circuit, a memory circuit, a bias circuit, a reference circuit, an analog-to-digital converter, another suitable circuit, or any combinations thereof.

In some embodiments, the second semiconductor chip 200 includes a second substrate 201. The second substrate 201 and the first substrate 101 may include similar or the same materials. For example, the second substrate 201 may include silicon, germanium, gallium, arsenic, and combinations thereof. In some embodiments, the second substrate 201 is in a form of SOI. In some embodiments, the second substrate 201 is a multi-layered or gradient substrate, hybrid orientation substrates, any combinations thereof and/or the like.

In some embodiments, the second semiconductor chip 200 includes a second metallization structure 204, a second inter-metal dielectric (IMD) layer 205, and a second inter-layer dielectric layer ILD-2 between the second metallization structure 204 and the second substrate 201. In some embodiments, the second metallization structure 204 includes a first metallization layer 2041, a top metallization layer 2043, and interconnect layers 2042 between the first metallization layer 2041 and the top metallization layer 2043. In some embodiments, the first metallization layer 2041 is disposed adjacent to the second inter-layer dielectric layer ILD-2, and the top metallization layer 2043 is disposed adjacent to an interface defined between the first semiconductor chip 100 and the second semiconductor chip 200. In addition, there are conductive contacts between the first metallization layer 2041 and the second substrate 201 for electrically connecting the second metallization structure 204 and electrical components (not shown) such as circuits, transistors or any suitable electrical components in the second substrate 201. In some embodiments, the second metallization structure 204 further includes conductive vias 2046 vertically disposed between metal layers of the second metallization structure 204 for electrical connection. In some embodiments, the second metallization structure 204 forms a second back-end-of-line (BEOL) structure for the second semiconductor chip 200.

Materials and fabrications of the second inter-layer dielectric layer ILD-2, the second metallization structure 204 and the second IMD layer 205 may be similar or essentially the same as those discussed for the first inter-layer dielectric layer ILD-1, the first metallization structure 104 and the first IMD layer 105, respectively. Those details are not repeated herein for the purpose of simplicity and clarity.

In some embodiments, the first semiconductor chip 100 and the second semiconductor chip 200 are bonded together through any suitable bonding techniques. The first semiconductor chip 100 and the second semiconductor chip 200 may be bonded together by a metal-to-metal bonding (e.g., copper-to-copper bonding), dielectric-to-dielectric bonding (e.g., oxide-to-oxide bonding), metal-to-dielectric bonding (e.g., oxide-to-copper bonding), another suitable bonding method, or any combinations thereof.

In some embodiments, a first bonding layer 106 is formed over the first metallization structure 104 and the first IMD layer 105, and a second bonding layer 206 is formed over the second metallization structure 204 and the second IMD layer 205. The first semiconductor chip 100 and the second semiconductor chip 200 may be bonded together by direct bonding between the first bonding layer 106 and the second bonding layer 206.

In some embodiments, the first bonding layer 106 and the second bonding layer 206 may also serve as passivation layers. The first bonding layer 106 and the second bonding layer 206 may include any suitable material for bonding. For example, the first bonding layer 106 and the second bonding layer 206 may be formed of one or more layers including silicon oxide, silicon nitride, silicon oxynitride, silicon carbide, silicon oxycarbide, undoped silicon glass, phosphosilicate glass, compounds thereof, composites thereof, combinations thereof, or the like. In one embodiment, the first bonding layer 106 includes a silicon nitride layer 1061 and a silicon oxide layer 1062. In one embodiment, the second bonding layer 206 includes a silicon nitride layer 2061 and a silicon oxide layer 2062. The first bonding layer 106 and the second bonding layer 206 may be deposited by any suitable method, such as spin-on coating, CVD, PECVD, or the like.

In some embodiments, after the first semiconductor chip 100 and the second semiconductor chip 200 are bonded by the first bonding layer 106 and the second bonding layer 206, the first substrate 101 of the first semiconductor chip 100 is patterned by a lithography patterning process and an etching process (such as anisotropical etching process) to form a first trench 310 in the TOV region A2. In some embodiments, the first trench 310 extends from the second surface 1012 (i.e., a back surface) of the first substrate 101 of the first semiconductor chip 100 to a predetermined depth in the first substrate 101. The lithographic patterning process may include photoresist coating (e.g., spin-on coating), soft baking, mask aligning, exposure, post-exposure baking, developing the photoresist, rinsing and drying (e.g., hard baking), another suitable process, or a combination of the foregoing processes.

In some embodiments, the lithographic patterning process is performed on a photoresist to form a patterned photoresist layer 301 on the second surface 1012 of the first substrate 101. After the patterned photoresist layer 301 is formed, a portion of the first substrate 101 that is not covered by the patterned photoresist layer 301 (i.e., exposed by the opening 3012 of the patterned photoresist layer 301) is etched by using the patterned photoresist layer 301 as a mask. The etching process may include a dry etching process, a wet etching process, a plasma etching process, a reactive ion etching (RIE) process, another suitable process, or a combination of the foregoing processes. In some embodiments, the etching process stops on an isolation bar 102E of the isolation structures 102 and may slightly recess the isolation bar 102E. The, bottom surface 310b of the first trench 310 is lower than the top surface 102a of the isolation bar 102E, as shown in FIG. 2A. Therefore, in this example, the isolation bar 102E may function as an etch stop layer in the etching process that is applied to form the first trench 310.

After the first trench 310 is formed, the patterned photoresist layer 301 is removed from the first substrate 101 by ashing, stripping or another suitable operation.

Next, an isolation lamination 110 (FIG. 2C) is formed on the first substrate 101 and along the sidewall 310s and the bottom surface 310b of the first trench 310. In some embodiments, the isolation lamination 110 may include several dielectric material layers, such as an outer dielectric layer 120, an inner dielectric layer 150, and a middle dielectric layer 130 between the outer dielectric layer 120 and the inner dielectric layer 150. Structures and methods for forming those layers of some embodiments are discussed in detail below. A person having ordinary skill in the art will appreciate that the layers of the isolation lamination 110 are provided for illustrative purposes and are not intended to limit the various embodiments to any particular applications.

Referring to FIG. 1 and FIG. 2B, method 1 includes a block 12 where an outer dielectric layer 120 is formed in the first trench 310. In some embodiments, the outer dielectric layer 120 includes a liner portion 121 in the first trench 310 and an upper portion 123 on the second surface 1012 of the first substrate 101. The liner portion 121 is conformally deposited on the sidewall 310s and the bottom surface 310b of the first trench 310. The thickness t1 of the liner portion 121 may be substantially the same as or different from (less than or greater than) the thickness t2 of the upper portion 123. In addition, in some embodiments, where the semiconductor device 10-1 is an image sensor device, the upper portion 123 may function as an anti-reflective coating (ARC) for the first semiconductor chip 100. In some embodiments, the upper portion 123 of the outer dielectric layer 120 can be further removed to expose the second surface 1012 of the first substrate 101, depending on practical applications.

In some embodiments, the outer dielectric layer 120 includes a high-k dielectric layer that has a dielectric constant higher than the dielectric constant of silicon oxide (about 3.9). In some embodiments, the outer dielectric layer 120 is a single dielectric layer or a multilayered dielectric structure. In some embodiments, when the outer dielectric layer 120 is a multilayered dielectric structure, at least one dielectric layer of the multilayered dielectric structure has a dielectric constant greater than 7. In some embodiments, the outer dielectric layer 120 is formed of one or more layers including Si₃N₄, AlO, Al₂O₃, TaO, Ta₂O₅, TiO, TiO₂, SrTiO₃, ZrO, ZrO₂, HfO, HfO₂, HfSiO, HfSiO₄, LaO, La₂O₃, YO, Y₂O₃, LaAlO₃, ZrSiO, BaSrTiO, BaTiO, StTiO, PbScTaO, compounds thereof, composites thereof, combinations thereof, or the like. The outer dielectric layer 120 may be formed using physical vapor deposition (PVD), atomic layer deposition (ALD), chemical vapor deposition (CVD), or any suitable deposition technique.

Referring to FIG. 1 and FIG. 2C, method 1 includes a block 13 where a middle dielectric layer 130 and an inner dielectric layer 150 are sequentially formed over the outer dielectric layer 120. In some embodiments, the middle dielectric layer 130 is formed over the first substrate 101 and on the outer dielectric layer 120. Therefore, the middle dielectric layer 130 is separated from the first substrate 101 by the outer dielectric layer 120.

In addition, the middle dielectric layer 130 may be a single dielectric layer or a multilayered dielectric structure. In one exemplified embodiment, the middle dielectric layer 130 includes a first oxide layer 130-1 on the outer dielectric layer 120 and a second oxide layer 130-2 on the first oxide layer 130-1. The first oxide layer 130-1 may include the first liner oxide 131 in the first trench 310 and the first upper oxide 133 over the second surface 1012 of the first substrate 101. Specifically, the first liner oxide 131 is formed on the liner portion 121 of the outer dielectric layer 120, and the first upper oxide 133 is formed on the upper portion 123 of the outer dielectric layer 120, as shown in FIG. 2C. The second oxide layer 130-2 may include the second liner oxide 135 in the first trench 310 and the second upper oxide 137 over the second surface 1012 of the first substrate 101. Specifically, the second liner oxide 135 is formed on the first liner oxide 131, and the second upper oxide 137 is formed on the first upper oxide 133, as shown in FIG. 2C. The middle dielectric layer 130 may be formed using PVD, ALD, CVD, or any suitable deposition technique.

After the middle dielectric layer 130 is formed, an inner dielectric layer 150 is conformally formed on the middle dielectric layer 130. The inner dielectric layer 150 may include a liner portion 151 in the first trench 310 and an upper portion 153 over the second surface 1012 of the first substrate 101. Specifically, the liner portion 151 is formed on the second liner oxide 135, and the upper portion 153 is formed on the second upper oxide 137, as shown in FIG. 2C. The inner dielectric layer 150 may include nitride (such as silicon nitride) or any suitable material, and may be formed using PVD, ALD, CVD, or any suitable deposition technique. In some embodiments, the outer dielectric layer 120, the middle dielectric layer 130, and the inner dielectric layer 150 are collectively referred to as an isolation lamination 110.

Referring to FIG. 1 and FIG. 2D, method 1 includes a block 14 where a patterned mask layer 302 is formed on the isolation lamination 110. The patterned mask layer 302 has an opening 3022 that is positioned within the first trench 310. Specifically, the opening 3022 of the patterned mask layer 302 exposes a bottom portion 110B of the isolation lamination 110 in the first trench 310, and remaining portions of the isolation lamination 110 are covered by the patterned mask layer 302. As shown in FIG. 2D, the vertical portions of the inner dielectric layer 150 in the first trench 310 are covered by the patterned mask layer 302. Details of the method for forming the patterned mask layer 302 in FIG. 2D are essentially the same as those discussed with reference to the patterned photoresist layer 301 in FIG. 2A. Those details are not repeated herein for the purpose of simplicity and clarity.

Referring to FIG. 1 and FIG. 2E, method 1 includes a block 15 where a second trench 320 is formed by extending the first trench 310 to penetrate the isolation lamination 110 and the underlying material layers until reaching the second metallization structure 204 of the second semiconductor chip 200. In some embodiments, an etching process is performed through the opening 3022 of the patterned mask layer 302, thereby removing the exposed bottom portion 110B of the isolation lamination 110 in the first trench 310, a portion of the isolation bar 102E, a portion of the first inter-layer dielectric layer ILD-1, a portion of the first IMD layer 105, portions of the first bonding layer 106, and portions of the second bonding layer 206 to form the second trench 320. In some embodiments, a dielectric portion 105c (FIG. 2D) of the first IMD layer 105 is positioned under the opening 3022 of the patterned mask layer 302, and metal traces of the first metallization structure 104 are arranged outside the dielectric portion 105c in order to facilitate the etching process for forming the second trench 320.

In some embodiments, the second trench 320 stops on the top metallization layer 2043 (e.g., the top surface 2043a of the top metallization layer 2043) of the second metallization structure 204, as shown in FIG. 2E. That is, the top metallization layer 2043 functions as an etch stop layer in the etching process. In addition, the second trench 320 is formed below the first trench 310, and communicates with the first trench 310. In some embodiments, the width W1 of the first trench 310 is greater than the width W2 of the second trench 320. The second trench 320 and the first trench 310 collectively form an elongated hole for receiving conductive material in the subsequent process.

After the second trench 320 is formed, the patterned photoresist layer 302 is removed by ashing, stripping or another suitable operation.

Referring to FIG. 1 and FIG. 2F, method 1 includes a block 16 where a conductive material 1600 is formed on the first substrate 101 to fill the second trench 320 and the first trench 310. In some embodiments, the conductive material 1600 includes gold, silver, copper, nickel, tungsten, titanium, aluminum, palladium and/or alloys thereof. In some embodiments, the conductive material 1600 overfills the second trench 320 and the first trench 310. In some embodiments, the conductive material 1600 is formed by, for example, an electroplating process, another suitable process or a combination thereof.

In some embodiments, one or more barrier layers (not shown) may be formed prior to the electroplating process. The barrier layer may be formed on the sidewalls of the first trench 310 and the second trench 320 and the bottom of the second trench 320 to prevent the subsequent conductive material from diffusing into the neighboring layers. The barrier layer is made of, for example, titanium, titanium nitride, tantalum, tantalum nitride, or combinations thereof. The barrier layer may be formed by ALD, CVD, plasma-enhanced CVD (PECVD), PVD, or plasma-enhanced PVD (PEPVD).

In addition, in some embodiments, a seed layer (not shown) may be formed over the barrier layer (not shown). The seed layer is made of, for example, copper, nickel, gold, or combinations thereof. The seed layer may be formed by PVD. Moreover, the seed layer may be alloyed with a material that improves the adhesive properties of the seed layer so that the seed layer acts as an adhesion layer. For example, the seed layer may be alloyed with a material, such as manganese or aluminum, which will migrate to the interface between the seed layer and the barrier layer and will enhance the adhesion between these two layers. The alloying material may be introduced during formation of the seed layer.

Referring to FIG. 1 and FIG. 2G, method 1 includes a block 17 where an excess portion of the conductive material 1600 is removed to form a conductive plug 160 in the first trench 310 and the second trench 320. In this exemplified embodiment, excess portions of the conductive material 1600, the inner dielectric layer 150 and the second oxide layer 130-2 are removed by a planarization process, such as a chemical mechanical polishing (CMP) process, or a combination of a plasma etch-back followed by the CMP process. In some embodiments, the first oxide layer 130-1 acts as a polish stop layer in this removal process so as to protect the underlying outer dielectric layer 120 and the first substrate 101 from CMP damage. After the removal process, the conductive plug 160 is formed. In addition, the remaining portions of the isolation lamination 110 form a dielectric structure DS. In some embodiments, as shown in FIG. 2G, the outer dielectric layer 120, the first oxide layer 130-1, the second liner oxide 135 and the liner portion 151 of the inner dielectric layer 150 are collectively referred to as a dielectric structure DS.

In some embodiments, the first semiconductor chip 100 and the second semiconductor chip 200 are electrically interconnected by the conductive plug 160. When either one or more of the middle dielectric layer 130, the isolation bar 102E, the first inter-layer dielectric layer ILD-1, the first IMD layer 105, the first bonding layer 106 and/or the second bonding layer 206 of the embodiments is made of oxide (e.g., silicon oxide), the conductive plug 160 can be referred to as a through-oxide via (TOV) that includes conductive material.

In some embodiments, the conductive plug 160 includes two portions, in which a first portion 162 extends from the backside (e.g., the second surface 1012) of the first substrate 101 to the first IMD layer 105, and a second portion 164 extends from the first metallization layer 1041 to the top metallization layer 2043 of the second metallization structure 204. Therefore, the conductive plug 160 penetrates the inner dielectric layer 150, the middle dielectric layer 130, the outer dielectric layer 120, the isolation bar 102E, the first inter-layer dielectric layer ILD-1, the first metallization structure 104, the first IMD layer 105, the first bonding layer 106 and the second bonding layer 206, and lands on the top metallization layer 2043 of the second metallization structure 204. The width (i.e., W1) of the first portion 162 may be greater than the width (i.e., W2) of the second portion 164.

In some embodiments, when incident radiation or incident light are converted by the photodetectors 103 (such as photodiodes) into an electric signal, the electric signal is sent to the logic circuits through a conductive path formed by the first metallization structure 104 of the first semiconductor chip 100 (e.g., a sensor wafer), the conductive plug 160 in the TOV region A2, and the second metallization structure 204 of the second semiconductor chip 200 (e.g., a ASIC wafer).

Referring to FIG. 1 and FIG. 2H, method 1 includes a block 18 where a coating layer 170 is formed over the first substrate 101 to cover the dielectric structure DS and the conductive plug 160. In some embodiments, the coating layer 170 covers the first oxide layer 130-1, the second liner oxide 135, the liner portion 151 and the top surface 160a of the conductive plug 160. The coating layer 170 prevents the material of the conductive plug 160 from diffusing into the neighboring layers. In some embodiments, the coating layer 170 is made of a dielectric material, such as silicon oxide, silicon nitride, silicon oxynitride, a low-k dielectric, doped glass (e.g. boron silicate glass), or combinations thereof. The coating layer 170 may be used as an anti-reflective coating (ARC) to enhance the performance of the semiconductor device 10-1. In some embodiments, the coating layer 170 may include a high-k dielectric such as Al₂O₃, Ta₂O₅, or the like. The coating layer 170 may be formed using any suitable deposition technique such as PVD, ALD, CVD, etc.

In some embodiments, the dielectric structure DS surrounds a portion of the sidewall (such as the sidewall 162s of the first portion 162) of the conductive plug 160 in the first substrate 101. In one exemplified embodiment, the liner portion 151 can be referred to as part or all of an inner dielectric layer 150 of the dielectric structure DS. The first liner oxide 131 and the second liner oxide 135 can be collectively referred to as a middle dielectric layer of the dielectric structure DS. The liner portion 121 can be referred to as part or all of an outer dielectric layer 120 of the dielectric structure DS.

In addition, in some embodiments, each of the liner portion 121 of the outer dielectric layer 120, the first liner oxide 131 and the second liner oxide 135 of the middle dielectric layer 130, and the liner portion 151 has an L-shaped cross section. Specifically, as shown in FIG. 2H, the outer dielectric layer 120 includes a bottom portion 122 that connects the liner portion 121 and extends to the sidewall of the conductive plug 160. For example, the bottom portion 122 is in contact with the sidewall 162s of the first portion 162 of the conductive plug 160. The bottom portion 122 and the liner portion 121 may include the same material(s), composites, or combination. In one exemplified embodiment, the bottom portion 122 covers a bottommost surface of the middle dielectric layer. In one exemplified embodiment, the bottom portion 122 covers the bottom surface 131b of the first liner oxide 131. Accordingly, the first liner oxide 131 is separated from the first substrate 101 and the isolation bar 102E by the outer dielectric layer 120.

During the process of manufacturing the above-mentioned semiconductor device, electrons typically remain near the upper surface of a substrate of a semiconductor chip, and thus a leakage current is formed. Leakage current degrades the reliability of the semiconductor device. In some embodiments, the outer dielectric layer 120 (e.g., including the liner portion 121) is formed between the first substrate 101 and the conductive plug 160 in the lateral direction, as shown in FIG. 2H. The outer dielectric layer 120 (e.g., including the liner portion 121) includes one or more high-k dielectric layers, and provides better isolation/passivation effect for the conductive plug 160. In some embodiments, at least one of the high-k dielectric layers has a dielectric constant higher than the dielectric constant of silicon oxide (about 3.9). In some embodiments, at least one of the high-k dielectric layers has a dielectric constant higher than approximately 7.0. Thus, a leakage current that flows in a lateral direction between the conductive plug 160 and the first substrate 101 can be greatly reduced, and the performance of the devices (such as the photodetectors 103) in the array region A1 can be improved. In addition, in some embodiments, the conductive plug 160 and the dielectric structure DS (with high-k dielectric liner) surrounding the conductive plug 160 may be collectively referred to as a TOV link structure. In addition, a keep-out zone Ak labeled in FIG. 2H is an area within the TOV region A2, and defined by a zone between the conductive plug 160 and the array region A1. Since the dielectric structure DS with a high-k dielectric liner provides better isolation/passivation effect for the conductive plug 160, the keep-out zone Ak can be reduced for greater flexibility in circuit design. For example, the width W3 of the keep-out zone Ak can be reduced by more than 3 times.

Referring to FIG. 1 and FIG. 2I, method 1 includes a block 19 where more components are incorporated into the first semiconductor chip 100 to enhance device performance. In some embodiments, where the semiconductor device 10-1 is an image sensor device, several metal grids 181 are formed on the coating layer 170 and disposed in a dielectric layer 183. The metal grids 181 are formed in the array region A1 of the first semiconductor chip 100 and positioned above the isolation structures 102. The metal grids 181 and the isolation structures 102 block light from passing between neighboring pixels, thereby reducing interpixel cross talk. The metal grids 181 may be formed of tungsten, copper, aluminum copper, another suitable metal, or a combination thereof. Color filters 188 and micro-lenses 189 are formed over the dielectric layer 183 and positioned on the gaps between the metal grids 181. The color filters 188 are positioned such that the incident radiation is directed thereon and therethrough. The color filters 188 may include a dye-based or pigment-based polymer for filtering a specific wavelength band of the incident radiation. The micro-lenses 189 are formed over the color filters 188 and configured to direct and focus the incident radiation toward specific radiation-sensing regions or devices (such as the photodetectors 103) in the first substrate 101. The micro-lenses 189 may have various shapes depending on a refractive index of a material used for the micro-lenses 189 and distance from a sensor surface.

Although FIG. 2I shows the outer dielectric layer 120 is a single layer that includes a high-k material layer, the present disclosure is not limited thereto. The outer dielectric layer 120 may be a multilayered dielectric structure that includes different dielectric materials. In some embodiments, the outer dielectric layer 120 may include an upper portion on the second surface 1012 of the first substrate 101 as an anti-reflective layer. In addition, the number of dielectric layers of the upper portion may be the same or different from the number of dielectric layers of the liner portion that surrounds the sidewall of the conductive plug 160. Some exemplified embodiments are provided below for illustration.

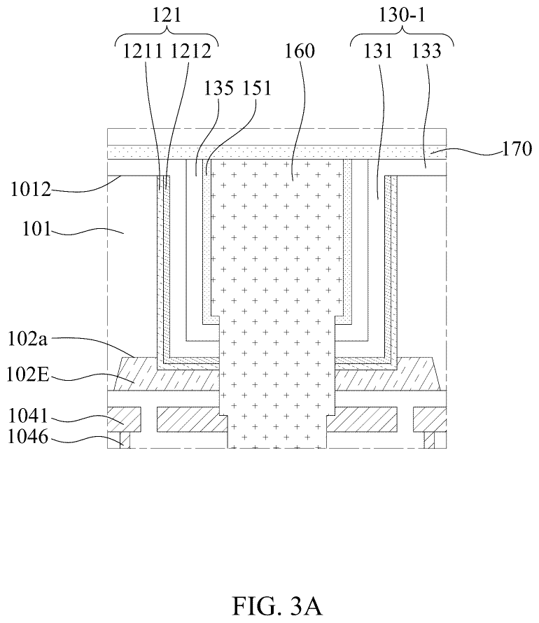

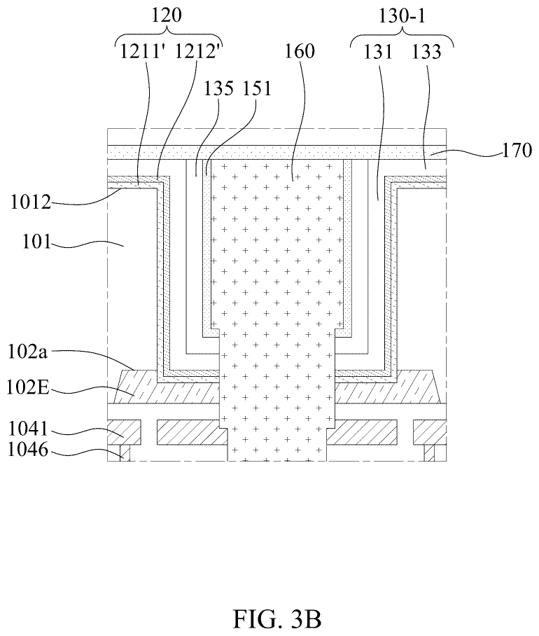

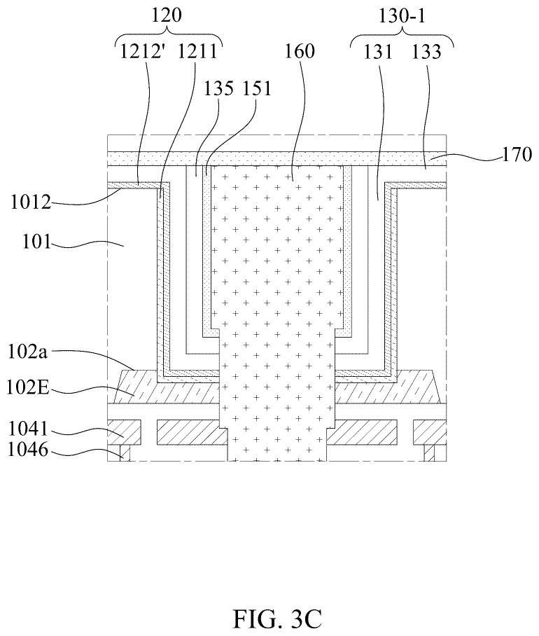

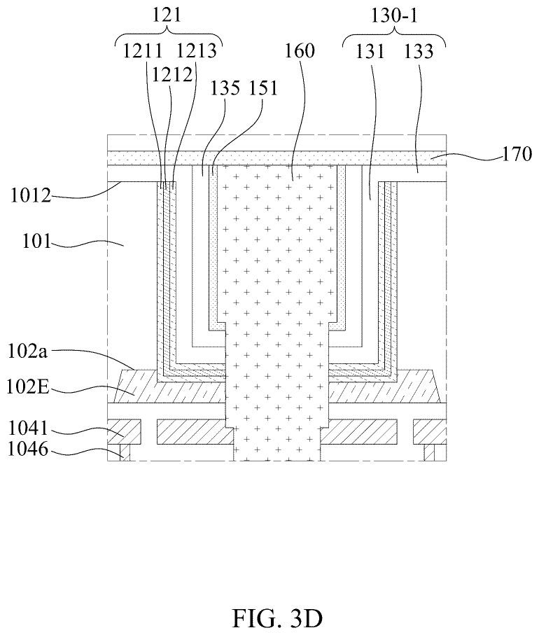

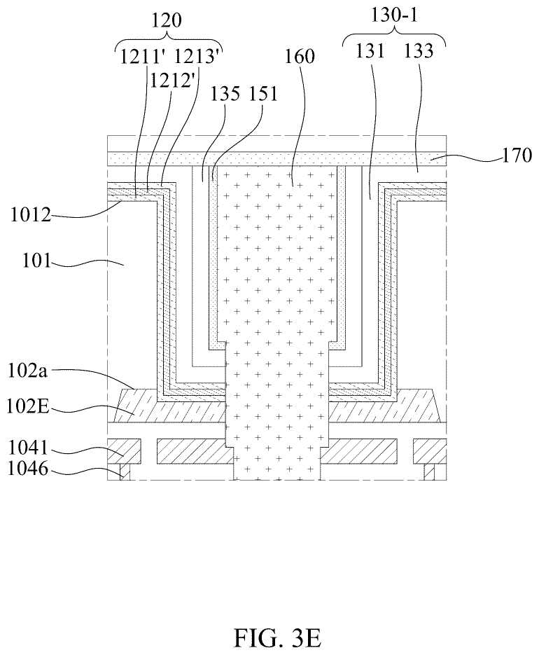

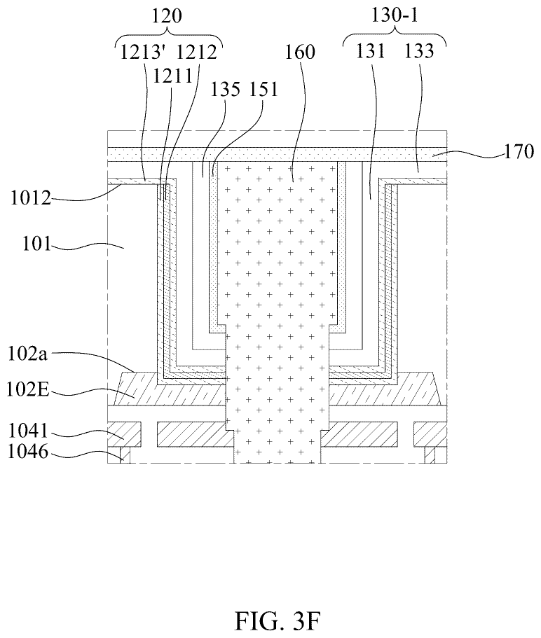

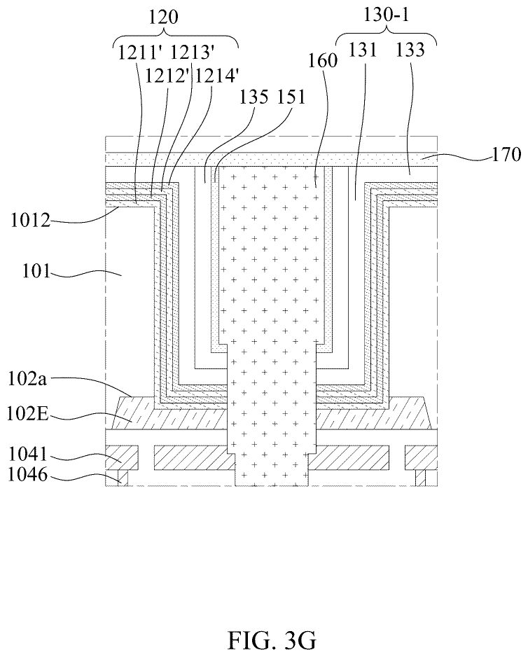

FIG. 3A-FIG. 3G illustrate enlarged cross-sectional views of a selected region R2 in the TOV region A2 shown in FIG. 2I in accordance with various embodiments. The features/components in FIG. 3A to FIG. 3G that are similar to or identical to the features/components in FIG. 2A to FIG. 2I are designated with similar or the same reference numbers. Details of the arrangement, materials and manufacturing methods of those similar or identical features/components shown in FIG. 3A to FIG. 3G are essentially the same as those discussed with reference to FIG. 2A to FIG. 2I, and are not repeated herein.

In some embodiments, as shown in FIG. 3A, the liner portion 121 can be referred to as an outer dielectric layer. The liner portion 121 includes two dielectric layers 1211 and 1212, and the top surfaces of the dielectric layers 1211 and 1212 are substantially level with the second surface 1012 of the first substrate 101. The dielectric layers 1211 and 1212 include different dielectric materials. The dielectric layer 1211 may be a native oxide layer, a silicon oxide layer, a silicon nitride layer, or a high-k dielectric layer. The dielectric layer 1212 may be a silicon oxide layer, a silicon nitride layer, or a high-k dielectric layer. In some embodiments, at least one of the dielectric layers 1211 and 1212 has a dielectric constant greater than 7.

In some embodiments, the dielectric layer 1211 is an Al₂O₃ layer, and the dielectric layer 1212 is a Ta₂O₅ layer. In some embodiments, the dielectric layer 1211 is a HfO₂ layer, and the dielectric layer 1212 is a Ta₂O₅ layer. Applicable materials of the dielectric layers 1211 and 1212 may refer to the exemplified materials of the outer dielectric layer 120 as described above. The dielectric layers 1211 and 1212 that have different materials may provide different functions. For example, the HfO₂ layer (k is about 25) greatly reduces a leakage current that laterally flows between the conductive plug 160 and the first substrate 101. The Ta₂O₅ layer (k is about 22) not only reduces leakage current but also has excellent moisture barrier properties. Combination of the dielectric layers 1211 and 1212 formed of different high-k materials that have different functions may improve the performance of the dielectric structure DS surrounding the conductive plug 160.

FIG. 3B illustrates an enlarged cross-sectional view of the selected region R2 in the TOV region A2 shown in FIG. 2I in accordance with some embodiments. The difference between the structures in FIG. 3B and FIG. 3A is the configuration of the outer dielectric layer 120. In FIG. 3A, the outer dielectric layer (which includes the dielectric layers 1211 and 1212) is formed in the trench and surrounds the sidewall 162s of the conductive plug 160, wherein the first oxide layer 130-1 is in contact with the second surface 1012 of the first substrate 101. In FIG. 3B, the dielectric layers 1211′ and 1212′ are formed on the second surface 1012 of the first substrate 101 and conformally formed in the trench, wherein the dielectric layer 1211′ is in contact with the second surface 1012 of the first substrate 101. That is, each of the dielectric layers 1211′ and 1212′ includes an upper portion over the second surface 1012 of the first substrate 101, as shown in FIG. 3B. In other words, the number of dielectric layers of an upper portion of the outer dielectric layer 120 is equal to the number of dielectric layers of a liner portion of the outer dielectric layer 120, as shown in FIG. 3B.

Applicable materials of the dielectric layers 1211′ and 1212′ in FIG. 3B may refer to the exemplified materials of the outer dielectric layer 120 as described above. The dielectric layers 1211′ and 1212′ that have different materials may provide different functions. For example, one of the dielectric layers, either the dielectric layer 1211′ or the dielectric layer 1212′ , is a Ta₂O₅ layer. For an image sensor (CIS) device, the Ta₂O₅ layer on the second surface 1012 of the first substrate 101 also functions as an anti-reflective layer.

FIG. 3C illustrates an enlarged cross-sectional view of the selected region R2 in the TOV region A2 shown in FIG. 2I in accordance with some embodiments. The difference between the structures in FIG. 3C and FIG. 3A is that the dielectric layer 1212′ in FIG. 3C is formed on the second surface 1012 of the first substrate 101 and conformally formed in the trench. That is, the dielectric layer 1212′ has an upper portion over the second surface 1012 of the first substrate 101.

In addition, the dielectric layer 1211 and a lower portion of the dielectric layer 1212′ in the trench are collectively referred to as a liner portion of the outer dielectric layer that surrounds the sidewall of the conductive plug 160. That is, the number of dielectric layers of an upper portion of the outer dielectric layer 120 may be less than the number of dielectric layers of a liner portion of the outer dielectric layer 120. In this exemplified embodiment, the upper portion of the outer dielectric layer 120 includes one dielectric layer (i.e., the portion of the dielectric layer 1212′ on the second surface 1012 of the first substrate 101) and the liner portion of the outer dielectric layer 120 includes two dielectric layers, as shown in FIG. 3C. Adding more high-k dielectric layers to form the liner portion of the outer dielectric layer 120 enhances properties such as passivation and electrical isolation of the outer dielectric layer 120, thereby improving the performance of the dielectric structure DS surrounding the conductive plug 160. Accordingly, the reliability of the semiconductor device can be improved.

FIG. 3D illustrates an enlarged cross-sectional view of the selected region R2 in the TOV region A2 shown in FIG. 2I in accordance with some embodiments. The difference between the structures in FIG. 3D and FIG. 3A is the number of dielectric layers of the outer dielectric layer. In FIG. 3D, the liner portion 121 that can be referred to as an outer dielectric layer includes three dielectric layers 1211, 1212 and 1213. The top surfaces of the dielectric layers 1211, 1212 and 1213 are substantially level with the second surface 1012 of the first substrate 101. In some embodiments, the dielectric layers 1211, 1212 and 1213 include different dielectric materials. The dielectric layer 1211 may be a native oxide layer, a silicon oxide layer, a silicon nitride layer, or a high-k dielectric layer. The dielectric layers 1212 and 1213 may be formed of silicon oxide, silicon nitride, or a high-k dielectric material. In some embodiments, at least one of the dielectric layers 1211, 1212 and 1213 has a dielectric constant greater than 7.

FIG. 3E illustrates an enlarged cross-sectional view of the selected region R2 in the TOV region A2 shown in FIG. 2I in accordance with some embodiments. The difference between the structures in FIG. 3E and FIG. 3B is the number of dielectric layers of the outer dielectric layer. In FIG. 3E, the outer dielectric layer 120 includes three dielectric layers 1211′, 1212′ and 1213′. In some embodiments, the dielectric layers 1211′, 1212′ and 1213′ include different dielectric materials. In some embodiments, at least one of the dielectric layers 1211′, 1212′ and 1213′ has a dielectric constant greater than 7. In addition, each of the dielectric layers 1211′, 1212′ and 1213′ has an upper portion over the second surface 1012 of the first substrate 101.

FIG. 3F illustrates an enlarged cross-sectional view of the selected region R2 in the TOV region A2 shown in FIG. 2I in accordance with some embodiments. The difference between the structures in FIG. 3F and FIG. 3D is that the dielectric layer 1213′ in FIG. 3F is formed on the second surface 1012 of the first substrate 101 and conformally formed in the trench. That is, the dielectric layer 1213′ has an upper portion over the second surface 1012 of the first substrate 101. As shown in FIG. 3F, the upper portion of the outer dielectric layer 120 includes one dielectric layer (i.e., the portion of the dielectric layer 1213′ on the second surface 1012 of the first substrate 101), and the liner portion of the outer dielectric layer 120 includes three dielectric layers. Adding more high-k dielectric layers to form the liner portion of the outer dielectric layer 120 enhances properties such as passivation and electrical isolation of the outer dielectric layer 120, thereby improving the performance of the dielectric structure DS surrounding the conductive plug 160. Accordingly, the reliability of the semiconductor device can be improved.

FIG. 3G illustrates an enlarged cross-sectional view of the selected region R2 in the TOV region A2 shown in FIG. 2I in accordance with some embodiments. The difference between the structures in FIG. 3G and FIG. 3E is the number of dielectric layers of the outer dielectric layer. In FIG. 3G, the outer dielectric layer 120 includes four dielectric layers 1211′, 1212′, 1213′ and 1214′. The dielectric layers 1211′, 1212′, 1213′ and 1214′ may include different dielectric materials. In some embodiments, at least one of the dielectric layers 1211′, 1212′, 1213′ and 1214′ has a dielectric constant greater than 7. In addition, each of the dielectric layers 1211′, 1212′, 1213′ and 1214′ has an upper portion over the second surface 1012 of the first substrate 101. Adding more high-k dielectric layers to form the outer dielectric layer 120 may enhance the properties such as passivation and electrical isolation of the outer dielectric layer 120, thereby improving the performance of the dielectric structure DS surrounding the conductive plug 160. Accordingly, the reliability of the semiconductor device can be improved.

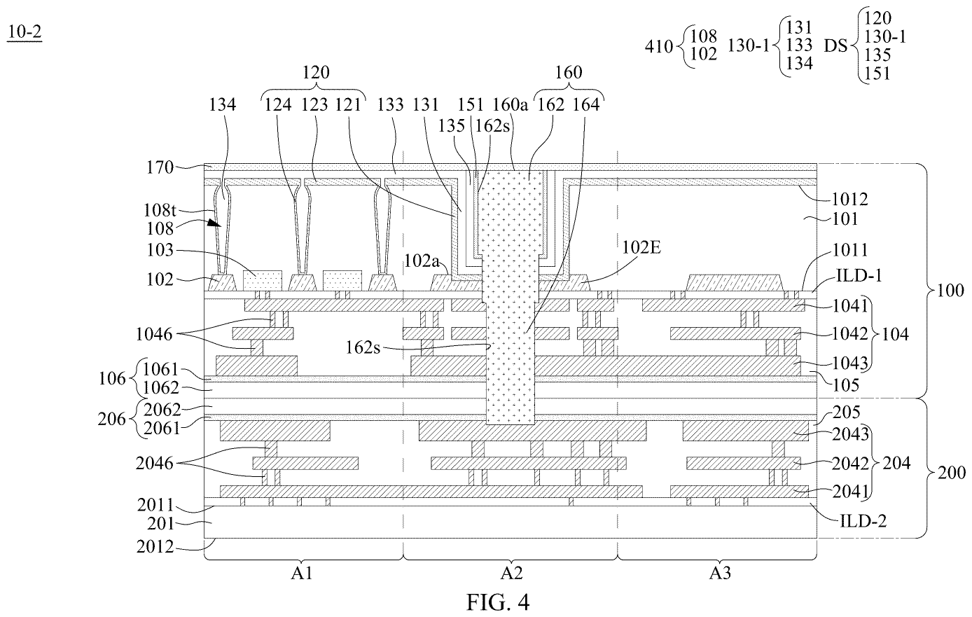

FIG. 4 illustrates a fragmentary cross-sectional view of a semiconductor device 10-2, in accordance with some embodiments of the present disclosure. The features/components in FIG. 4 that are similar to or identical to the features/components in FIG. 2H are designated with similar or the same reference numbers. Details of the arrangement, materials and manufacturing methods of those similar or identical features/components shown in FIG. 4 are essentially the same as those discussed with reference to FIG. 2H, and are not repeated herein.

In some embodiments, the semiconductor device 10-2 further includes backside deep trench isolations (B-DTI) 410 to enhance electrical isolation between the devices (such as the photodetectors 103). The backside deep trench isolations (B-DTI) 410 are buried in the first substrate 101, and extend from the second surface 1012 towards the first surface 1011 of the first substrate 101. The backside deep trench isolations 410 are vertically formed in the first substrate 101 to separate the first substrate 101 into a plurality of pixel areas. Each of the backside deep trench isolations (B-DTI) 410 includes an isolation structure 102 and a deep trench isolation structure 108 landing on the isolation structure 102. The deep trench isolation structures 108 may be substantially aligned with the isolation structures 102. The aspect ratio of the deep trench isolation structure 108 may be greater than that of the isolation structure 102.

In some embodiments, the outer dielectric layer 120 further includes the second liner portions 124 on the sidewalls of the deep trenches 108t. In some embodiments, the first oxide layer 130-1 further includes the oxide fill layers 134 in the deep trenches 108t. In some embodiments, the deep trenches 108t and the first trench 310 may be formed simultaneously using an anisotropic etching process.

The second liner portions 124 may function as passivation layers and separate the first substrate (e.g., silicon substrate) 101 from the oxide fill layers 134. The second liner portions 124 in the deep trenches 108t and the liner portion 121 surrounding the conductive plug 160 may include the same dielectric material and may be formed simultaneously. The second liner portion 124 is a single dielectric layer or a multilayered dielectric structure. In some embodiments, the second liner portion 124 includes a high-k dielectric layer that has a dielectric constant higher than the dielectric constant of silicon oxide (about 3.9). In some embodiments, the second liner portion 124 includes a high-k dielectric layer that has a dielectric constant greater than 7. In addition, in some embodiments, the first liner oxide 131, the first upper oxide 133 and the oxide fill layers 134 are formed simultaneously.

In this exemplified embodiment, a B-DTI (backside deep trench isolation) scheme is incorporated into the semiconductor device 10-2 to perform excellent electrical isolation or passivation. In some embodiments, where the semiconductor device 10-2 is an image sensor device, the backside deep trench isolations (B-DTI) 410 further improve the optical isolation. The deep trench isolation structures 108 of the B-DTI 410 and the dielectric structure DS can be formed in the same process loop without higher cost.

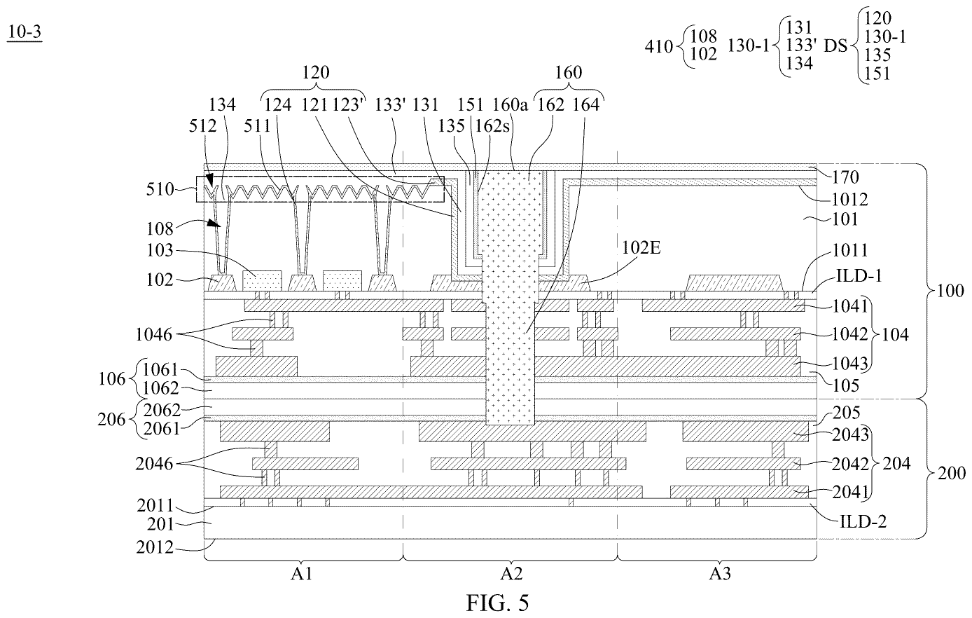

FIG. 5 illustrates a fragmentary cross-sectional view of a semiconductor device 10-3 in accordance with some embodiments of the present disclosure. The features/components in FIG. 5 that are similar to or identical to the features/components in FIG. 2H are designated with similar or the same reference numbers. Details of the arrangement, materials and manufacturing methods of those similar or identical features/components shown in FIG. 5 are essentially the same as those discussed with reference to FIG. 2H, and are not repeated herein.

In some embodiments, where the semiconductor device 10-3 is an image sensor device, the semiconductor device 10-3 further includes a light absorption structure 510 on the second surface 1012 of the first substrate 101 to obtain better optical performance. In some embodiments, the light absorption structure 510 includes microstructures 511 that form a textured surface at a portion of the second surface 1012 of the first substrate 101. As shown in FIG. 5, the microstructures 511 are located at pixel regions, and several grooves 512 between the microstructures 511 are recessed toward the first surface 1011 of the first substrate 101. The microstructures 511 may form a random groove pattern or a periodic groove pattern. The textured surface formed by the microstructures 511 may be a bumpy, wavy, or rough surface. The formation of the microstructures 511 (or the grooves 512) changes the surface topography of the pixel regions. The microstructures 511 provides more exposed surface area per horizontal unit area and reduces reflected light by optimizing the incident angle of light. Increasing the exposed surface area and reducing reflected light increase the effective light incident area and in turn increases the incident light intensity received by the pixel regions. As a result, the quantum efficiency of the pixels of the semiconductor device 10-3 is improved.

In some embodiments, the upper portion 123′ of the outer dielectric layer 120 is conformally formed on the second surface 1012 of the first substrate 101 and the textured surface of the light absorption structure 510. For example, the upper portion 123′ is conformally deposited on the wavy surfaces of the microstructures 511 (or the grooves 512). The second liner portions 124 in the deep trenches 108t, the upper portion 123′ on the textured surface of the light absorption structure 510, and the liner portion 121 surrounding the conductive plug 160 may include the same dielectric material (i.e., one or more high-k dielectric materials) and may be formed simultaneously.

In addition, in some embodiments, the first oxide layer 130-1 includes the first liner oxide 131, the first upper oxide 133′ on the second surface 1012 of the first substrate 101, and the oxide fill layers 134 in the deep trenches 108t. The first upper oxide 133′ fills the grooves 512 between the microstructures 511. In some embodiments, the first liner oxide 131, the first upper oxide 133′ and the oxide fill layers 134 are formed simultaneously.

Although two semiconductor chips or two wafers with a TOV link structure (i.e., the conductive plug 160 and the dielectric structure DS with a high-k dielectric liner surrounding the conductive plug 160) are exemplified in the aforementioned descriptions, three or more stacked semiconductor chips or wafers that have different functions may be applicable with the use of the TOV link structure of the embodiments.

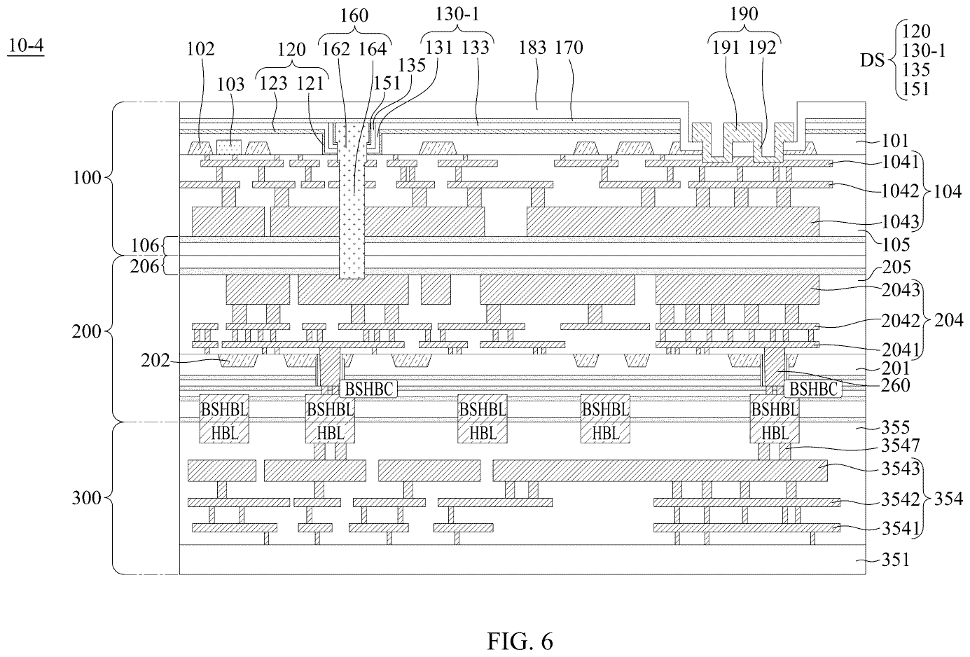

FIG. 6 illustrates a fragmentary cross-sectional view of a semiconductor device 10-4 in accordance with some embodiments of the present disclosure. The features/components in FIG. 6 that are similar to or identical to the features/components in FIG. 2H are designated with similar or the same reference numbers. Details of the arrangement, materials and manufacturing methods of those similar or identical features/components shown in FIG. 6 are essentially the same as those discussed with reference to FIG. 2H, and are not repeated herein.

In some embodiments, the semiconductor device 10-4 includes a first semiconductor chip 100, a second semiconductor chip 200 and a third semiconductor chip 300. In some embodiments, the first semiconductor chip 100 may be a CMOS image sensor (CIS) device that includes a photodetectors 103 or any suitable device or circuit. The CIS chip is configured for capturing light and converting it into an electrical signal. In some other embodiments, the first semiconductor chip 100 may include embedded deep trench capacitors (DTC).

In addition, the first semiconductor chip 100 further includes a conductive bonding pad 190 to provide electrical connection between the first semiconductor chip 100 and an external component (not shown). For example, a power source is connected to the conductive bonding pad 190 to supply power to the semiconductor device 10-4. In some embodiments, the conductive bonding pad 190 includes a planar portion 191 disposed upon an STI layer, and one or more vertical portions 192 that extend perpendicularly downward from the planar portion 191 to reach the first metallization layer 1041 through the isolation structure 102. The conductive bonding pad 190 may be made of aluminum (Al), copper (Cu), another suitable conductive material, or their combination (e.g., AlCu).

The second semiconductor chip 200 may be a semiconductor application specific integrated circuit (ASIC) chip, which is configured for a particular application. In some embodiments, the second semiconductor chip 200 includes several logic circuits such as an analog-to-digital converter, data processing circuits, memory circuits, bias circuits, reference circuits, any combinations thereof and/or the like.

The third semiconductor chip 300 may be a memory chip, which is configured for data storage. In some embodiments, the third semiconductor chip 300 includes memory devices such as dynamic random access memory (DRAM) devices, static random access memory (SRAM) devices, or a combination thereof. In some embodiments, the third semiconductor chip 300 includes a third substrate 351, a third metallization structure 354 and the third IMD layer 355. The third metallization structure 354 includes a first metallization layer 3541, a top metallization layer 3543, and interconnect layers 3542 between the first metallization layer 3541 and the top metallization layer 3543. The third metallization structure 354 further includes hybrid bond link structures HBL in the third IMD layer 355, and the hybrid bond link structures HBL are formed adjacent to an interface between the third semiconductor chip 300 and the second semiconductor chip 200. The hybrid bond link structures HBL are electrically connected to the top metallization layer 3543 by the hybrid bond contacts 3547.

In addition, the first semiconductor chip 100 may be electrically connected to the second semiconductor chip 200 by a TOV link structure (i.e., the conductive plug 160 and the dielectric structure DS with a high-k dielectric liner surrounding the conductive plug 160) in accordance with some embodiments. In addition, the second semiconductor chip 200 may be electrically connected to the third semiconductor chip 300 by the back-side through silicon vias (BTSV) 260, the back-side hybrid bond link structures BSHBL in the second semiconductor chip 200, and the hybrid bond link structures HBL in the third semiconductor chip 300. Specifically, the back-side through silicon vias (BTSV) 260 extend from the first metallization layer 2041 of the second metallization structure 204 to the back-side hybrid bond link structures BSHBL in the second semiconductor chip 200. The back-side hybrid bond link structures BSHBL are in direct contact with the hybrid bond link structures HBL. In addition, the back-side through silicon vias (BTSV) 260 and the back-side hybrid bond link structures BSHBL are electrical coupling by back-side hybrid bond connection structures BSHBC. The back-side hybrid bond connection structure BSHBC may be in physical contact with the BTSV 260 and the back-side hybrid bond link structure BSHBL, as shown in FIG. 6.

In some embodiments, when incident radiation or incident light are converted by the photodetectors 103 (such as photodiodes) into an electric signal, the electric signal is sent to the logic circuits through a conductive path formed by the first metallization structure 104 of the first semiconductor chip 100 (e.g., a sensor wafer), a TOV link structure (including the conductive plug 160) in the TOV region A2, and the second metallization structure 204 of the second semiconductor chip 200 (e.g., a ASIC wafer) for data processing. The processed data is transmitted through a conductive path formed by the second metallization structure 204 of the second semiconductor chip 200, the BTSV 260, BSHBC, BSHBL, HBL and the third metallization structure 354 to the memory components of the third semiconductor chip 300 (e.g., a DRAM wafer) for data storage.

Accordingly, in this exemplified embodiment, a TOV link structure (i.e., the conductive plug 160 and the dielectric structure DS with a high-k dielectric liner surrounding the conductive plug 160) is incorporated into three semiconductor chips (or wafers) for electrically connecting the first and second semiconductor chips (or wafers), thereby improving the performance of electrical isolation/passivation and/or optical isolation of the semiconductor device 10-4.

Various embodiments or examples described herein offer several advantages. According to the embodiments of the present disclosure, a link structure (such as a TOV link structure) that includes a high-k dielectric liner surrounding a conductive plug is adopted in a semiconductor device to interconnect stacked chips or wafers. The link structure with the high-k dielectric liner provides excellent passivation and electrical isolation, so that a leakage current between the conductive plug and the substrate (such as the first substrate 101) can be greatly reduced. Accordingly, the performance of the devices (such as the photodetectors 103) in the array region A1 can be improved. In addition, according to the embodiments, a keep-out zone between the conductive plug and the pixel region can be further reduced for greater flexibility in circuit design because of the high-quality link structure with high electrical isolation and passivation characteristics. Therefore, wide product application is also feasible and achievable.

Some embodiments of the present disclosure provide a semiconductor device. The semiconductor device includes a first semiconductor chip, a second semiconductor chip, a conductive plug, and a dielectric structure. The first semiconductor chip includes a first metallization structure on a first substrate. The second semiconductor chip includes a second metallization structure on a second substrate. The second semiconductor chip is bonded to the first semiconductor chip. The conductive plug extends from the first semiconductor chip to the second semiconductor chip for electrically connecting the first metallization structure and the second metallization structure. The dielectric structure surrounds a portion of the sidewall of the conductive plug. The dielectric structure includes a middle dielectric layer between an outer dielectric layer and an inner dielectric layer. The outer dielectric layer is formed between the first substrate and the middle dielectric layer. The dielectric constant of the outer dielectric layer is greater than that of the middle dielectric layer.

Some embodiments of the present disclosure provide a semiconductor device. The semiconductor device includes a first semiconductor chip, a second semiconductor chip, a conductive plug, and a dielectric structure. The first semiconductor chip includes a first metallization structure on a first substrate. The second semiconductor chip includes a second metallization structure on a second substrate. The second semiconductor chip is bonded to the first semiconductor chip. The conductive plug penetrates the first semiconductor chip and extends to the second semiconductor chip for electrically connecting the first metallization structure and the second metallization structure. The dielectric structure surrounds a portion of the sidewall of the conductive plug. The dielectric structure includes a middle dielectric layer between an outer dielectric layer and an inner dielectric layer. The dielectric constant of the outer dielectric layer is greater than the dielectric constant of the middle dielectric layer, and the outer dielectric layer has an L-shaped cross section between the conductive plug and the first substrate.

Some embodiments of the present disclosure provide a method for forming the semiconductor device. The method includes providing a first semiconductor chip and a second semiconductor chip. The first semiconductor chip includes a first substrate and a first metallization structure formed on the first substrate. The second semiconductor chip includes a second substrate and a second metallization structure on the second substrate. The method further includes bonding the first metallization structure of the first semiconductor chip to the second metallization structure of the second semiconductor chip. The method further includes forming a first trench extending from a second surface of the first substrate to a predetermined depth in the first substrate. The method further includes forming an isolation lamination along the sidewall and the bottom surface of the first trench. The isolation lamination includes a middle dielectric layer between an outer dielectric layer and an inner dielectric layer. The dielectric constant of the outer dielectric layer is greater than 3.9. The outer dielectric layer separates the middle dielectric layer from the first substrate. The method further includes forming a second trench by removing a bottom portion of the isolation lamination in the first trench. The second trench extends to the second metallization structure of the second semiconductor chip. The method further includes forming a conductive plug in the first trench and the second trench.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first semiconductor chip comprising a first metallization structure on a first substrate;
a second semiconductor chip comprising a second metallization structure on a second substrate, wherein the second semiconductor chip is bonded to the first semiconductor chip;
a conductive plug extending from the first semiconductor chip to the second semiconductor chip for electrically connecting the first metallization structure and the second metallization structure; and
a dielectric structure surrounding a portion of a sidewall of the conductive plug, and the dielectric structure comprising:
a middle dielectric layer between an outer dielectric layer and an inner dielectric layer,
wherein the outer dielectric layer is formed between the first substrate and the middle dielectric layer, and a dielectric constant of the outer dielectric layer is greater than a dielectric constant of the middle dielectric layer.

2. The semiconductor device of claim 1, wherein the outer dielectric layer includes a high-k dielectric layer that has a dielectric constant higher than silicon oxide.

3. The semiconductor device of claim 1, wherein the outer dielectric layer is a multilayered dielectric structure.

4. The semiconductor device of claim 3, wherein at least one dielectric layer of the multilayered dielectric structure has a dielectric constant greater than 7.

5. The semiconductor device of claim 1, wherein the first metallization structure is formed on a first surface of the first substrate, and the dielectric structure comprises an upper portion on a second surface of the first substrate, wherein the second surface is opposite to the first surface.

6. The semiconductor device of claim 5, wherein the dielectric structure comprises a liner portion surrounding the portion of the sidewall of the conductive plug, and the number of dielectric layers of the upper portion is less than the number of dielectric layers of the liner portion.

7. The semiconductor device of claim 5, further comprising:
a light absorption structure on the second surface of the first substrate, wherein the upper portion of the dielectric structure is extended to and conformally formed on microstructures of the light absorption structure.

8. The semiconductor device of claim 1, wherein the outer dielectric layer comprises:
a bottom portion extending to the sidewall of the conductive plug, wherein the bottom portion covers a bottommost surface of the middle dielectric layer.

9. The semiconductor device of claim 8, further comprising:
an isolation bar, formed over the first metallization structure and buried in the first substrate,
wherein the conductive plug penetrates the isolation bar, and the bottom portion of the outer dielectric layer extends on the isolation bar.

10. The semiconductor device of claim 1, further comprising:
deep trench isolations, vertically formed in the first substrate and separating the first substrate into pixel areas; and
a device formed between adjacent two of the deep trench isolations, wherein the outer dielectric layer of the dielectric structure is extended to form liners of the deep trench isolations.

11. A semiconductor device, comprising:
a first semiconductor chip comprising a first metallization structure on a first substrate;
a second semiconductor chip bonded to the first semiconductor chip, and the second semiconductor chip comprising a second metallization structure on a second substrate; and
a conductive plug penetrating the first semiconductor chip and extending to the second semiconductor chip for electrically connecting the first metallization structure and the second metallization structure; and
a dielectric structure surrounding a portion of a sidewall of the conductive plug, and the dielectric structure comprising:
a middle dielectric layer formed between an outer dielectric layer and an inner dielectric layer, wherein a dielectric constant of the outer dielectric layer is greater than a dielectric constant of the middle dielectric layer, and the
outer dielectric layer has a L-shaped cross section between the conductive plug and the first substrate.

12. The semiconductor device of claim 11, wherein the outer dielectric layer covers a bottommost surface of the middle dielectric layer.

13. The semiconductor device of claim 11, wherein the outer dielectric layer comprises:
an upper portion on a second surface of the first substrate,
wherein the first metallization structure is formed on a first surface of the first substrate, and the second surface is opposite to the first surface.

14. The semiconductor device of claim 11, wherein the outer dielectric layer comprises:
a liner portion extending from the second surface of the first substrate towards the first surface of the first substrate.

15. The semiconductor device of claim 14, wherein the upper portion and the liner portion of the outer dielectric layer comprise different laminations of material layers.

16. The semiconductor device of claim 11, wherein the outer dielectric layer is a multilayered dielectric structure, and at least one dielectric layer of the multilayered dielectric structure has a dielectric constant equal to or higher than 9.

17. A method for forming a semiconductor device, comprising:
providing a first semiconductor chip comprising a first metallization structure on a first substrate and a second semiconductor chip comprising a second metallization structure on a second substrate;
bonding the first metallization structure of the first semiconductor chip to the second metallization structure of the second semiconductor chip;
forming a first trench extending from a second surface of the first substrate to a predetermined depth in the first substrate;
forming an isolation lamination along a sidewall and a bottom surface of the first trench, wherein the isolation lamination comprises a middle dielectric layer between an outer dielectric layer and an inner dielectric layer, and the outer dielectric layer has a dielectric constant greater than 3.9 and separates the middle dielectric layer from the first substrate;
forming a second trench by removing a bottom portion of the isolation lamination in the first trench, wherein the second trench extends to the second metallization structure of the second semiconductor chip; and
forming a conductive plug in the first trench and the second trench.

18. The method of claim 17, wherein before the second trench is formed, the method further comprises:
forming a patterned mask layer on the isolation lamination and the first trench, wherein the patterned mask layer comprises a hole in the first trench, and the hole exposes the bottom portion of the isolation lamination in the first trench.

19. The method of claim 18, wherein the second trench as formed removes the bottom portion of the isolation lamination and penetrates an isolation bar, a first inter-layer dielectric layer, a first inter-metal dielectric layer and bonding layers of the first semiconductor chip and the second semiconductor chip; and
a remaining portion of the isolation lamination surrounds a portion of a sidewall of the conductive plug after the conductive plug is formed.

20. The method of claim 17, wherein the outer dielectric layer is deposited on the sidewall and the bottom surface of the first trench prior to forming the second trench.
